(19) United States
(12) Patent Application Publication
(10) Pub. No.: US 2020/0187360 A1
(43) Pub. Date: Jun. 11, 2020

(54) DISPLAY AND ELECTRONIC DEVICE

(71) Applicant: SHARP KABUSHIKI KAISHA, Sakai City (JP)

(72) Inventor: KENICHI SANUKI, Sakai City (JP)

(21) Appl. No.: 16/700,673

(22) Filed: Dec. 2, 2019

(30) Foreign Application Priority Data
Dec. 6, 2018 (JP) 2018-229029

(51) Int. Cl. H05K 1/18; G06F 3/041; G06F 3/047

(52) U.S. Cl. CPC H05K 1/189; G06F 3/0412; G06F 3/047; G06F 2203/04103; H05K 2201/10136; H05K 2201/2009; H05K 2201/10128

(57) ABSTRACT

A display includes a film and an FPC joined to an end of the film, and a protruding portion is formed in a joining part of the end and the FPC.

### BACKGROUND

### 1. Field

The present disclosure relates to a display and an electronic device including the display.

### 2. Description of the Related Art

In recent years, a touch panel built-in electronic device such as a smartphone remarkably tends to have a narrower width of a frame of a housing. As touch panels coping with such narrowing, an in-cell touch panel and an on-cell touch panel are generally used. However, the touch panels have a problem of being difficult to deal with an increase in definition and double-speed display of a display image, or the like.

In order to cope with the increase in definition and double-speed display of the display image described above, a film-shaped touch panel (hereinafter, “film”) is used. Here, for reducing the width of the frame of the housing, a flexible printed circuit (hereinafter, “FPC”) joined to an end of the film is requested to be bent from a part corresponding to a vicinity of an end surface of the end toward a display unit (such as an LCD). When such bending is performed, however, a part of the end in the film, which surrounds an intersection where the end surface of the end and a side surface of the FPC cross in plan view, is damaged due to stress concentration.

As a measure of suppressing the damage described above, it is considered that a reinforcement member disclosed in, for example, Japanese Unexamined Patent Application Publication No. 2013-59984 (published on Apr. 4, 2013) is applied to the FPC.

In a case where the part to be damaged is reinforced by the reinforcement member of Japanese Unexamined Patent Application Publication No. 2013-59984, however, the reinforcement member interferes with an anisotropic conductive adhesive film (ACF) by which the film is joined to the FPC and a thickness of a joining part of the film and the FPC has a variation. Then, a joining failure is caused because of such interference and variation. Therefore, the reinforcement member of Japanese Unexamined Patent Application Publication No. 2013-59984 is difficult to be used when the film is used, so that the FPC is requested to be bent at a part away from the end surface of the end in order to avoid the damage due to stress concentration described above.

In this case, double-sided tape is inevitably used to fix the FPC to glass and a bending position of the FPC is requested to be shifted to a tip end side of the frame of the housing by an amount of a space where the double-sided tape is attached. As a result, the width of the frame increases by the shift amount of the bending position of the FPC, so that the width of the frame is difficult to be reduced when the film is used.

An aspect of the disclosure is made in view of the aforementioned problems and a width of a frame of a housing in an electronic device is made narrower than a width of a frame of the related art while a damage of an end of a film, which is included in a joining part of the film and an FPC, is suppressed.

### SUMMARY

In order to cope with the aforementioned problems, a display according to an aspect of the disclosure is a display at least one of which is provided in an electronic device, and includes: a touch panel of a film shape; and a flexible printed circuit joined to an end of the touch panel, in which in a joining part of the end and the flexible printed circuit, a stress concentration suppressing portion that suppresses concentration of stress on a specific part of the end is formed by using at least one of the touch panel, a wire on the touch panel, and the flexible printed circuit.

In order to cope with the aforementioned problems, an electronic device according to an aspect of the disclosure is an electronic device including at least one display, in which the display includes: a touch panel of a film shape; and a flexible printed circuit joined to an end of the touch panel, and in a joining part of the end and the flexible printed circuit, a stress concentration suppressing portion that suppresses concentration of stress on a specific part of the end is formed by using at least one of the touch panel, a wire on the touch panel, and the flexible printed circuit.

### Advantageous Effects of Invention

An aspect of the disclosure advantageously makes a width of a frame of a housing in an electronic device narrower than a width of a frame of the related art while suppressing a damage of an end of a film which is included in a joining part of the film and an FPC.

### BRIEF DESCRIPTION OF THE DRAWINGS

FIG. 1A is a sectional view illustrating a schematic structure of a display according to Embodiments 1 to 3 of the disclosure;

FIG. 1B is a plan view illustrating a schematic structure of a film and an FPC according to Embodiment 1 of the disclosure;

FIG. 1C is a plan view illustrating a schematic structure of a joining part and a periphery of the joining part according to Embodiment 1 of the disclosure;

FIG. 2 is a plan view illustrating a schematic structure of a joining part and a periphery of the joining part according to Embodiment 2 of the disclosure;

FIG. 3A is a plan view illustrating a schematic structure of a joining part and a periphery of the joining part according to Embodiment 3 of the disclosure;

FIG. 3B is a sectional view illustrating a schematic structure of the display according to Embodiment 3 of the disclosure;

FIG. 4 is a plan view illustrating an example of a variation of a stress concentration suppressing portion according to an aspect of the disclosure; and

FIG. 5 is a sectional view illustrating a schematic structure of a display of the related art.

### DESCRIPTION OF THE EMBODIMENTS

### Embodiment 1

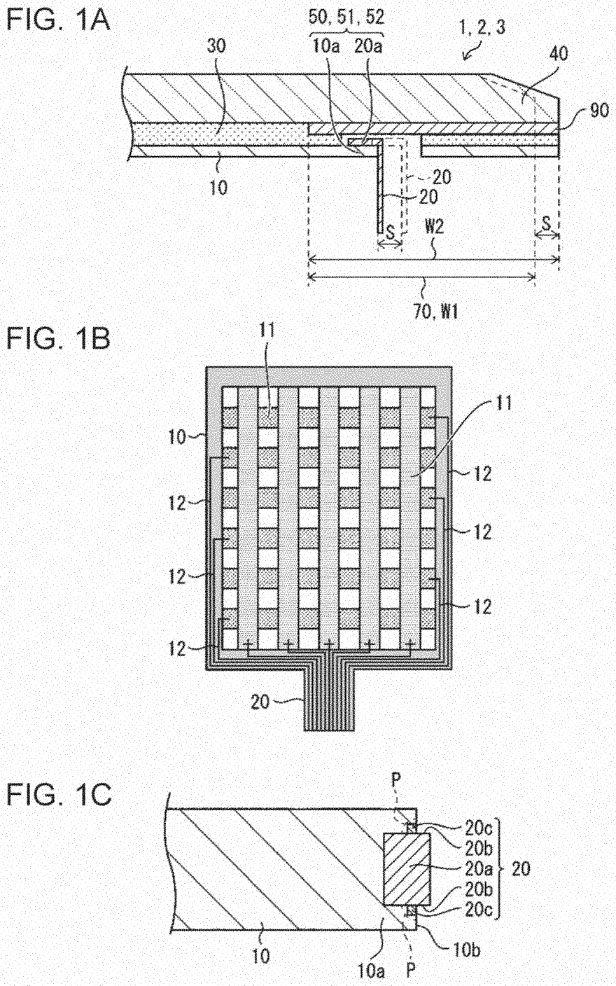

An embodiment of the disclosure will be described in detail with reference to FIGS. 1A to 1C. Description will be given below by taking a smartphone as an example of an electronic device according to the embodiment of the disclosure. Note that, as the electronic device according to an aspect of the disclosure, in addition to the smartphone, a portable game device, a tablet terminal, or the like is able to be exemplified. Moreover, the number of components, such as a display, which are included in the electronic device according to the aspect of the disclosure may be single or multiple.

### <Outline of Display>

A display 1 illustrated in FIGS. 1A to 1C is provided in a smartphone (electronic device: not illustrated). The smartphone is a multifunctional portable telephone having functions of both a personal computer, a personal digital assistant (PDA: portable information terminal), and the like.

As illustrated in FIG. 1A, the display 1 includes a film (touch panel of a film shape) 10, a flexible printed circuit (FPC) 20, an optical clear adhesive (OCA) 30, glass 40, and decorative print 90.

In addition, though not illustrated, a display unit is arranged at a position on a lower side (center side of an inside of a housing of the smartphone: hereinafter, “lower side”) of the film 10 in the sheet. In other words, the display 1 has a structure in which the film 10 is overlapped with the display unit. The display unit is a display panel such as an LCD or an organic EL display and various kinds of information and images are displayed in a display region of the display 1.

The film 10 detects that an operation object (e.g. finger of a user: not illustrated) contacts or is in the proximity of the glass 40 and receives an input operation of the user. On a surface of the film 10, a plurality of electrodes 11 are arranged in a matrix manner as illustrated in FIG. 1B, and when the operation object contacts or is in the proximity of the glass 40, an electrostatic capacity between the electrodes 11 changes. On a surface (on the touch panel) of the film 10, a plurality of wires 12 are arranged along an edge of the film 10 and one electrode 11 and one wire 12 are connected. The wire 12 is, for example, an Ag wire.

The FPC 20 is a substrate obtained by forming an electric circuit in a base material in which a base film (such as polyimide) having an insulating property and a thin film shape and conductive metal (such as copper foil) are bonded. An IC chip (not illustrated) is mounted on the FPC 20 and the IC chip functions as a touch panel controller. Moreover, on a surface of the FPC 20, the plurality of wires 12 are arranged as illustrated in FIG. 1B and connected to the IC chip or the like. The change in the electrostatic capacity described above is output to the IC chip or the like from the electrode 11 through the wire 12.

Note that, FIG. 1B illustrates a state before the FPC 20 is bent (for detail, refer to <Joining part> described below), for convenience of the description.

The OCA 30 is an adhesive sheet of a film shape as illustrated in FIG. 1A. When the OCA 30 is interposed between the film 10 and the glass 40, the film 10 and the glass 40 are bonded through the OCA 30. The glass 40 is, for example, strengthened glass and forms a design panel of the housing of the smartphone. An edge of the glass 40 forms a part of a frame 70 of the housing. The decorative print 90 is applied in a region between the OCA 30 and the glass 40 along the edge of the glass 40 and forms the frame 70 into a decorative frame.

### <Joining Part>

As illustrated in FIG. 1A, an end 10a of the film 10 and a tip end portion 20a of the FPC 20 are joined by an anisotropic conductive adhesive film (ACF: not illustrated). The end 10a and the tip end portion 20a form a joining part 50.

As illustrated in FIG. 1A, the FPC 20 is bent to the lower side so that a portion of the FPC 20 near the connecting part as the joining part 50 contacts an end surface 10b of the end 10a. The similar is also applied to Embodiments 2 and 3.

Moreover, as illustrated in FIG. 1C, a protruding portion 20c protrudes from each of two side surfaces 20b of the tip end portion 20a, which cross the end surface 10b of the end 10a in plan view. The protruding portion 20c has a column shape and is joined to the end 10a in a state of being overlapped with corresponding one of two parts (specific parts) P in a tip of the end 10a.

The two parts P described above are regions of the end 10a, which surround two intersections where the end surface 10b of the end 10a and the side surfaces 20b of the tip end portion 20a cross in plan view, and are parts where stress is concentrated when the FPC 20 is bent as illustrated in FIGS. 1A and 1C. In the following description, the two parts P described above where stress is concentrated are referred to as “stress concentrated parts P”.

In this manner, the protruding portion 20c is overlapped with the corresponding one of the two stress concentrated parts P, so that the two stress concentrated parts P are reinforced and a damage of a part that may be damaged due to stress concentration in the end 10a is able to be suppressed beforehand. In other words, the protruding portion 20c functions as a stress concentration suppressing portion that suppresses concentration of stress in a specific part of the end 10a.

The protruding portion 20c has a simple shape and is thus easily formed. In addition, the protruding portion 20c is able to be provided also in the FPC 20 with a compact size, for example, without increasing a surface area of the tip end portion 20a. As a result, it is possible to reduce a manufacturing cost and achieve the FPC including the protruding portion with a compact size as a whole.

Note that, a shape and a size of the protruding portion 20c and a part where the protruding portion 20c is arranged in the end 10a are able to be subjected to any design change in accordance with a size, a position, and the like of a part where stress is concentrated in the end 10a, in other words, a part that may be damaged. That is, the protruding portion 20c may have any shape, size, and the like as long as enabling reinforcement of the part where stress concentration can be caused.

### <Reduction of Width of Frame>

When the protruding portion 20c as the stress concentration suppressing portion as described above is provided in the joining part 50, specifically, the tip end portion 20a of the FPC 20, the width of the frame of the housing in the smartphone is able to be made narrower than that of a smartphone of the related art. A reason therefor will be described below.

In a case of trying to reduce a width of a frame of a housing in a smartphone (not illustrated) including a conventional display 100 illustrated in FIG. 5, a conventional FPC 200 is requested to be bent at a part corresponding to a vicinity of the end surface 10b of the end 10a in the film 10 (refer to FIG. 1A). However, needless to say, the protruding portion 20c is not provided in the conventional FPC 200. Thus, when bending as described is performed, the regions (refer to the stress concentrated parts P illustrated in FIG. 1C) in the end 10a, which surround two intersections where the end surface 10b of the end 10a and side surfaces of the FPC 200 cross in plan view, are damaged due to stress concentration.

In a case where a reinforcement member for reinforcing the two regions described above is used to suppress such stress concentration, the reinforcement member interferes with an ACF (not illustrated) by which the film 10 and the FPC 200 are joined and a joining part of the film 10 and the FPC 200 has a variation in thickness. Then, a joining failure is caused because of such interference and variation. Therefore, the reinforcement member described above is difficult to be used in the display 100 of the related art. Thus, in order to avoid a damage of the end 10a due to stress concentration, the FPC 200 is requested to be bent at a part away from the end surface 10b of the end 10a.

In this case, as illustrated in FIG. 5, double-sided tape 60 is inevitably used to fix the FPC 200 to the glass 40 and a bending position of the FPC 200 is requested to be shifted to a right side (tip end side of the frame 700) of the sheet by an amount of a space where the double-sided tape 60 is attached. As a result, a width W2 of the frame 700 of the housing is requested to be designed by considering a shift amount S of the bending position of the FPC 200.

Meanwhile, according to the display 1 in which the protruding portion 20c is provided in the tip end portion 20a of the FPC 20, the FPC 20 is able to be bent near the end surface 10b of the end 10a. As a result, it is unnecessary to consider the shift amount S of the bending position of the FPC 200, which is generated in the related art, and a width W1 of the frame 70 of the housing is able to be made narrower than the width W2 by an amount of at least the shift amount S which is removed, as illustrated in FIG. 1A.

### Embodiment 2

Another embodiment of the disclosure will be described below. Note that, for convenience of the description, a member having the same function as that of the member described in the aforementioned embodiment will be given the same reference sign and the description thereof will not be repeated. The similar is also applied to Embodiment 3.

### <Joining Part>

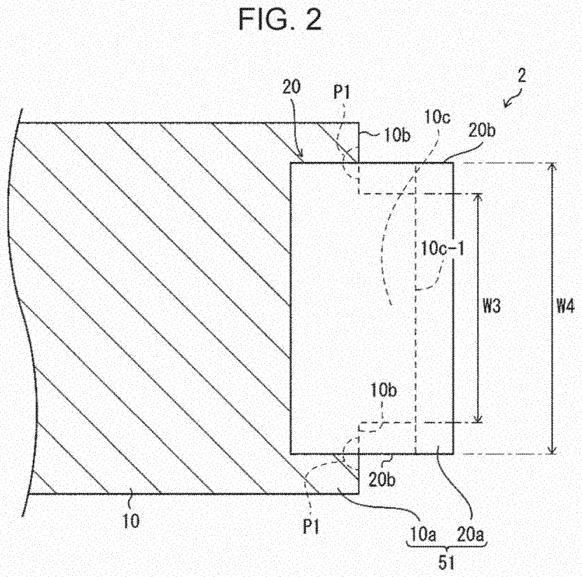

In a display 2 according to Embodiment 2, the end 10a of the film 10 has a convex shape as illustrated in FIG. 2. In addition, in the display 2, a plate width W4 of the tip end portion 20a of the FPC 20 is wider than a width W3 of a convex portion 10c of the end 10a and the tip end portion 20a is joined to the end 10a so as to cover the convex portion 10c. In other words, the end 10a having the convex portion 10c and the tip end portion 20a whose plate width W4 is wider than the width W3 of the convex portion 10c of the end 10a form a joining part 51.

When shapes and the like of the end 10a and the tip end portion 20a are provided as described above, the side surfaces 20b of the FPC 20 do not cross an end surface 10c-1 of the convex portion 10c in plan view in a vicinity of the end surface 10c-1 of the convex portion 10c, which is a bending position of the FPC 20, as illustrated in FIG. 2. In other words, the convex portion 10c has no part where stress concentration is caused due to bending of the FPC 20.

On the other hand, the end surface 10b of the end 10a crosses the side surfaces 20b of the FPC 20 in plan view similarly to Embodiment 1. However, the FPC 20 is not bent at a part corresponding to a vicinity of the end surface 10b of the end 10a in the film 10. As a result, stress concentration is not caused in regions P1 of the end 10a, which surround two intersections where the end surface 10b of the end 10a and the side surfaces 20b of the FPC 20 cross in plan view.

In this manner, when the end 10a has the convex shape and the plate width W4 of the tip end portion 20a is made wider than the width W3 of the convex portion 10c of the end 10a so that the tip end portion 20a covers the convex portion 10c, a part where stress is concentrated is able to be removed in the end 10a. In other words, a combination of the convex portion (specific portion in the touch panel of the film shape) 10c and the tip end portion (specific portion in the flexible printed circuit) 20a forms a stress concentration suppressing portion.

Further, according to the display 2 that has the end 10a and the tip end portion 20a with the shapes and sizes as described above, the FPC 20 is able to be bent in the vicinity of the end surface 10c-1 (corresponding to the end surface 10b of the end 10a in Embodiment 1) of the convex portion 10c. As a result, it is unnecessary to consider the shift amount S (refer to FIG. 5) of the bending position of the FPC 200, which is generated in the related art, and the width W1 of the frame 70 of the housing is able to be made narrower than the width W2 of the frame 700 of the related art by an amount of at least the shift amount S which is removed, as illustrated in FIG. 1A.

### Embodiment 3

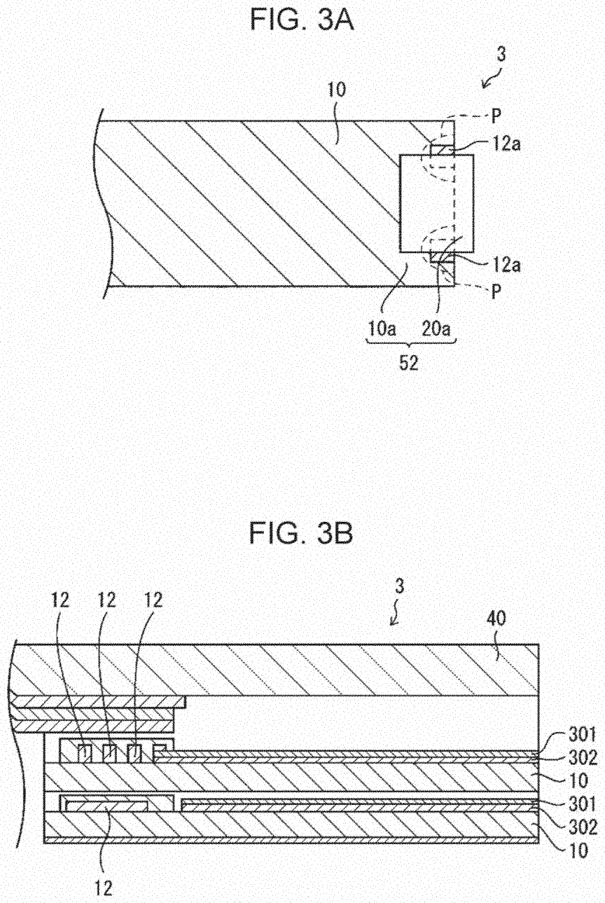

In a display 3 according to Embodiment 3, as illustrated in FIG. 3A, reinforcement portions 12a are formed by using the wires 12 at the two stress concentrated parts P (refer to Embodiment 1) on the surface of the end 10a. Then, the end 10a, on which the reinforcement portions 12a are formed, and the tip end portion 20a form a joining part 52.

Note that, FIG. 3B is a sectional view illustrating a structure of a vicinity of an end opposite to the end 10a of the film 10 in the display 3 and illustrates a more detailed structure than the sectional view of FIG. 1A. In FIG. 3B, an ITO 301 is an indium tin oxide (ITO) film for a touch panel and a transparent conductive film. An IML 302 is a film (index matching layer) that adjusts a refractive index so as to reduce a difference of a refractive index caused by whether the ITO 301 is provided. Arrangement of the ITO 301 is able to make a wire of the touch panel hard to view.

Specifically, as illustrated in FIG. 3B, the reinforcement portions 12a are formed by using the plurality of wires 12 (for example, Ag wires) arranged along the edge of the film 10 on the surface of the film 10 (refer to FIG. 1B). A shape and a size of the reinforcement portions 12a are only requested to be a shape and a size that are sufficient to cover the surfaces of the stress concentrated parts P, for example. In other words, the size and the shape may be any size and shape as long as no stress concentration is caused in the stress concentrated parts P.

Note that, parts where the reinforcement portions 12a are arranged are not limited to the two stress concentrated parts described above. The reinforcement portions 12a may be arranged at any parts on the surface of the end 10a as long as being specific parts, in which stress is concentrated due to bending of the FPC 20.

However, when a thickness of the reinforcement portions 12a is greater than a thickness of other wires 12, the joining part 52 of the film 10 and the FPC 20 may have a variation in thickness and a joining failure may be caused. Thus, the thickness of the reinforcement portions 12a is desired to be substantially the same as the thickness of other wires 12.

In this manner, when the reinforcement portions 12a are arranged at the two stress concentrated parts P on the surface of the end 10a, the two stress concentrated parts P are reinforced and a damage of a specific part that may be damaged due to stress concentration in the end 10a is suppressed. In other words, the reinforcement portions 12a function as stress concentration suppressing portions.

Further, according to the display 3 in which the reinforcement portions 12a are arranged at the stress concentrated parts P on the surface of the end 10a, similarly to Embodiment 1, the FPC 20 is able to be bent near the end surface 10b of the end 10a. As a result, it is unnecessary to consider the shift amount S (refer to FIG. 5) of the bending position of the FPC 200, which is generated in the related art, and the width W1 of the frame 70 of the housing is able to be made narrower than the width W2 of the frame 700 of the related art by an amount of at least the shift amount S which is removed, as illustrated in FIG. 1A.

### [Variation of Stress Concentration Suppressing Portion]

The stress concentration suppressing portion described in Embodiments 1 to 3 is merely an example and is assumed to have various variations.

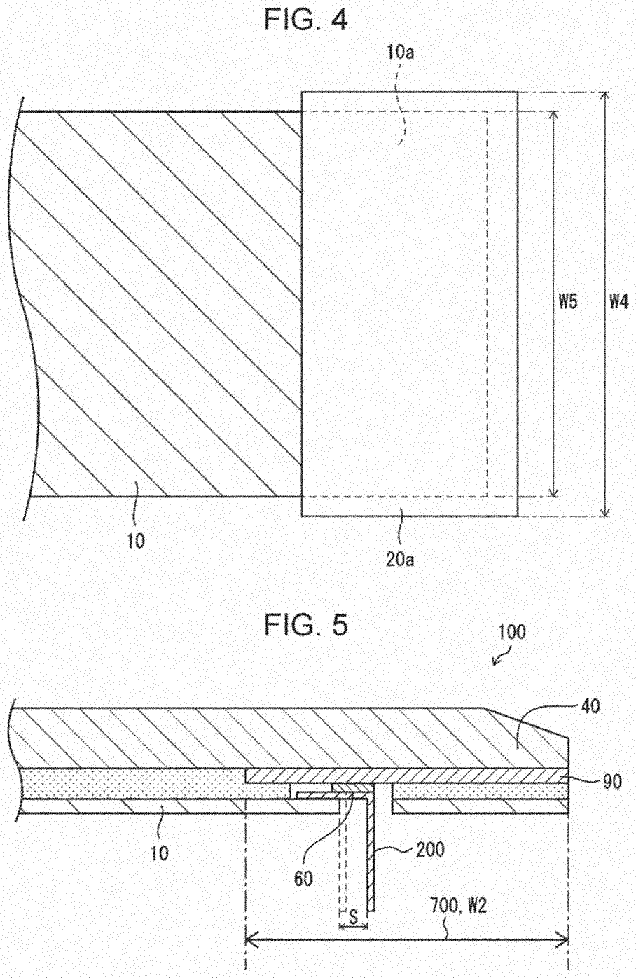

For example, as illustrated in FIG. 4, the plate width W4 of the tip end portion 20a of the FPC 20 may be made wider than a width W5 of the end 10a and a whole of the end 10a may be covered with the tip end portion 20a. In this case as well, similarly to Embodiment 2, the end 10a has no part where stress concentration is caused due to bending of the FPC 20. That is, the tip end portion 20a illustrated in FIG. 4 functions as the stress concentration suppressing portion.

As a result, also when the tip end portion 20a as illustrated in FIG. 4 is formed as the stress concentration suppressing portion, the width W1 of the frame 70 of the housing is able to be made narrower than the width W2 of the frame 700 of the related art while a damage of a specific part of the end 10a due to stress concentration is avoided.

In other words, the stress concentration suppressing portion according to an aspect of the disclosure is only requested to be formed by using at least one of the film 10, the wire 12, and the FPC 20 in the joining part of the end 10a in the film 10 and the FPC 20.

### CONCLUSION

A display (1, 2, 3) according to an aspect 1 of the disclosure is a display at least one of which is provided in an electronic device, and includes: a touch panel of a film shape (film 10); and a flexible printed circuit (FPC 20) joined to an end (10a) of the touch panel, in which in a joining part (50, 51, 52) of the end and the flexible printed circuit, a stress concentration suppressing portion (protruding portion 20c, combination of convex portion 10c and tip end portion 20a, reinforcement portion 12a) that suppresses concentration of stress on a specific part (stress concentrated part P) of the end is formed by using at least one of the touch panel, a wire (12) on the touch panel, and the flexible printed circuit.

According to the aforementioned configuration, the stress concentration suppressing portion is formed in the joining part of the end of the touch panel of the film shape (hereinafter, “touch panel”) and the flexible printed circuit (hereinafter, “FPC”). Thus, even when the FPC is bent near an end surface of the end of the touch panel, for example, by forming stress concentration suppressing portions in regions of the end, which surround two intersections where the end surface of the end and side surfaces of the FPC cross in plan view, it is possible to suppress concentration of stress in the regions.

Thus, while a damage of the end of the touch panel is suppressed, a bending position of the FPC is able to be made on an inner side of a housing of the electronic device than a bending position in the related art, and a width of a frame of the housing is able to be reduced by an amount of displacement of the bending position to the inner side.

Accordingly, while a damage of the end of the touch panel, which is included in the joining part of the touch panel and the FPC, is avoided, the width of the frame of the housing in the electronic device is able to be made narrower than a width of a frame of the related art (hereinafter, “frame width reduction”).

Moreover, for example, in a case where a corresponding part is reinforced by another member different from an existing part or an existing member of the display in order to suppress stress concentration, another member interferes with an anisotropic conductive adhesive film (ACF) by which the touch panel and the FPC are joined and a thickness of the joining part has a variation. Then, a joining failure is caused because of such interference and variation. Meanwhile, according to the aforementioned configuration, the stress concentration suppressing portion is formed by an existing part or an existing member of the display, a problem of the joining failure is also avoided.

In the display (1, 2) according to an aspect 2 of the disclosure, the stress concentration suppressing portion may be formed by at least one of a specific portion (convex portion 10c) in the end and a specific portion (protruding portion 20c, tip end portion 20a) in the flexible printed circuit, in the aspect 1.

According to the aforementioned configuration, when the stress concentration suppressing portion formed by at least one of a first portion and a second portion is provided in the joining part, it is possible to achieve both suppression of the damage of the end and the frame width reduction.

In the display (1) according to an aspect 3 of the disclosure, the stress concentration suppressing portion may be formed by a protruding portion (20c) protruding from a side surface, crossing an end surface of the end in plan view, of the flexible printed circuit, and the protruding portion may be joined to the end in a state of being overlapped with the specific part (stress concentrated part P), in the aspect 1 or 2.

According to the aforementioned configuration, when the protruding portion that protrudes from the side surface of the FPC is provided in the joining part as the stress concentration suppressing portion, it is possible to achieve both suppression of the damage of the end and the frame width reduction. Moreover, the protruding portion is able to be easily formed only by protruding from the side surface of the FPC and difficulty of the formation is not affected by a size of the FPC itself. Thus, it is possible to suppress a manufacturing cost and achieve a compact size of the FPC including the protruding portion as a whole.

In the display (2) according to an aspect 4 of the disclosure, the end may have a convex shape, a tip end portion (20a) of the flexible printed circuit may have a plate width (W4) wider than a width (W3) of a convex portion (10c) of the end and may be joined to the end (10a) so as to cover the convex portion, and the stress concentration suppressing portion may be formed by the convex portion and the tip end portion, in the aspect 1 or 2.

According to the aforementioned configuration, when the stress concentration suppressing portion formed by the convex portion of the touch panel and the tip end portion of the FPC is provided in the joining part, it is possible to achieve both suppression of the damage of the end and the frame width reduction.

In the display (3) according to an aspect 5 of the disclosure, a reinforcement portion (12a) arranged at the specific part (stress concentrated part P) on a surface of the end may be formed as the stress concentration suppressing portion by using the wire (12), in the aspect 1.

According to the aforementioned configuration, when the reinforcement portion formed by using the wire on the touch panel is provided in the joining part as the stress concentration suppressing portion, it is possible to achieve both suppression of the damage of the end and the frame width reduction.

An electronic device according to an aspect 6 of the disclosure is an electronic device including at least one display (1, 2, 3), in which the display includes: a touch panel of a film shape (film 10); and a flexible printed circuit (FPC 20) joined to an end (10a) of the touch panel, and in a joining part (50, 51, 52) of the end and the flexible printed circuit, a stress concentration suppressing portion (protruding portion 20c, combination of convex portion 10c and tip end portion 20a, reinforcement portion 12a) that suppresses concentration of stress on a specific part (stress concentrated part P) of the end is formed by using at least one of the touch panel, a wire on the touch panel, and the flexible printed circuit.

According to the aforementioned configuration, it is possible to achieve the electronic device in which a width of a frame of a housing is reduced while a damage of the end of the touch panel, which is included in the joining part of the touch panel of the film shape and the FPC, is suppressed.

### [Additional Matter]

The disclosure is not limited to each of the embodiments described above, and may be modified in various manners within the scope indicated in the claims and an embodiment achieved by appropriately combining techniques disclosed in different embodiments is also encompassed in the technical scope of the disclosure. Further, by combining the techniques disclosed in each of the embodiments, a new technical feature may be formed.

The present disclosure contains subject matter related to that disclosed in Japanese Priority Patent Application JP 2018-229029 filed in the Japan Patent Office on Dec. 6, 2018, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display at least one of which is provided in an electronic device, the display comprising:
a touch panel of a film shape; and
a flexible printed circuit joined to an end of the touch panel, wherein
in a joining part of the end and the flexible printed circuit, a stress concentration suppressing portion that suppresses concentration of stress on a specific part of the end is formed by using at least one of the touch panel, a wire on the touch panel, and the flexible printed circuit.

2. The display according to claim 1, wherein the stress concentration suppressing portion is formed by at least one of a specific portion in the end and a specific portion in the flexible printed circuit.

3. The display according to claim 1, wherein
the stress concentration suppressing portion is formed by a protruding portion protruding from a side surface, crossing an end surface of the end in plan view, of the flexible printed circuit, and
the protruding portion is joined to the end in a state of being overlapped with the specific part.

4. The display according to claim 1, wherein
the end has a convex shape,
a tip end portion of the flexible printed circuit has a plate width wider than a width of a convex portion of the end and is joined to the end so as to cover the convex portion, and
the stress concentration suppressing portion is formed by the convex portion and the tip end portion.

5. The display according to claim 1, wherein a reinforcement portion arranged at the specific part on a surface of the end is formed as the stress concentration suppressing portion by using the wire.

6. An electronic device including at least one display, wherein
the display comprising:
a touch panel of a film shape; and
a flexible printed circuit joined to an end of the touch panel, and
in a joining part of the end and the flexible printed circuit, a stress concentration suppressing portion that suppresses concentration of stress on a specific part of the end is formed by using at least one of the touch panel, a wire on the touch panel, and the flexible printed circuit.
